(19) United States
(12) Patent Application Publication
(10) Pub. No.: US 2001/0017397 A1
(43) Pub. Date: Aug. 30, 2001

(54) Thin-film resistor and method of fabrication

(76) Inventor: Jia-Sheng Lee, Hsin-Chu City (TW)

Correspondence Address: WINSTON HSU, 5 F, No. 389, Fu-Ho Road, Yung-Ho City, Taipei Hsien, 234, TW

(21) Appl. No.: 09/800,650

(22) Filed: Mar. 8, 2001

Related U.S. Application Data
(62) Division of application No. 09/330,039, filed on Jun. 11, 1999.

(51) Int. Cl. H01L 29/00

(52) U.S. Cl. 257/536

(57) ABSTRACT

A clipped thin-film resistor with an out-gassing preventing layer formed on a dielectric layer of a semiconductor substrate, and an isolated resistor layer interposed between the underlying out-gassing preventing layer and an overlying protective layer is provided to electrically connect with a semiconductor device fabricated on the semiconductor substrate. Two tungsten plugs, electrically connecting a metal wire with the isolated resistor layer, are positioned atop two respective ends of the resistor layer. Each tungsten plug first fills a self-aligned wet etched via formed within the protective layer atop two respective ends of the resistor layer and then etched back. The protective layer serves to protect the resistor layer from damage during the formation of the via.

### BACKGROUND OF THE INVENTION

1. Field of the Invention

The present invention relates to a thin-film resistor, and more particularly, to a clipped thin-film resistor for use on a semiconductor wafer.

2. Description of the Prior Art

Hitherto, many types of resistive components in the ICs of a semiconductor wafer have been developed, such as the gate conductive layer of the semiconductor wafer, doped layers, functioning as resistance components, and thin-film resistors. However, the main problem of both the gate conductive layers and doped layers is their low resistance. To be of practical use, these components must therefore be manufactured at a large enough size to increase their resistance to a sufficient level; but, the nature of the small line widths of the gate conductive layers and the doped layers make them unsuitable for use in semiconductor processes. As well, the use of silicon as a conducting material in the gate conductive layers and doped layers produces variable conductivity in the resistive components in the presence of temperature change, making their resistance unstable. Thus, in order to produce a resistive component of low conductivity and stable resistance, the use of a thin-film resistor is essential.

Please refer to FIG. 1. FIG. 1 is a schematic sectional diagram of a typical thin-film resistor positioned on a semiconductor wafer. A thin-film resistor 19 is positioned on a semiconductor wafer 11 and comprises a dielectric layer 10, two conductive layers 12, an insulating layer 14, and a resistor layer 18. The dielectric layer 10 is positioned on the semiconductor wafer 11. The two conductive layers 12 are positioned at a predetermined area of the dielectric layer 10. The insulating layer 14 is positioned on the two conductive layers 12 and comprises two separate openings 16, one on each of the two conductive layers 12. The resistor layer 18 is positioned at a predetermined area of the insulating layer 14 and fills in the two openings 16. Since the two conductive layers 12 contact the resistor layer 18 at separate points, they function as electrical terminals of the resistor layer 18 when the semiconductor wafer 11 electrically links with external components.

During processing of the thin-film resistor 19, the two conductive layers 12 are first positioned at a predetermined area of the dielectric layer 10. The result produces an uneven surface on the semiconductor wafer 11. Thus, as the insulating layer 14 and the resistor layer 18 are deposited on the semiconductor wafer 11, respectively, a difficulty in step coverage occurs whereby thickness of the resistor layer 18 becomes uneven. Connection of the conductive layers 12 with the thinner portions of the resistor layer 18 leads to a greater resistance than connection with the thicker portions. Therefore, the difference in thickness of the resistor layer 18 results in unstable resistance, making it difficult to achieve the required semiconductor circuit specifications.

### SUMMARY OF THE INVENTION

It is therefore a primary objective of the present invention to provide a thin-film resistor for use in a semiconductor wafer, and a method of its formation to solve the above-mentioned problems.

In a preferred embodiment, the present invention provides a thin-film resistor on a dielectric layer of a semiconductor wafer. A resistor island is formed comprising of an isolating layer and a resistor layer positioned respectively on the dielectric layer, and a protective layer laminated on the resistor layer. The protective layer has two self-aligned wet etched vias formed within the protective layer atop two respective ends of the resistor layer. An insulating layer is formed on the semiconductor wafer covering the resistor island, and two metal wires are positioned atop each respective end of the resistor layer to electrically connect with the resistor layer.

In another embodiment of the present invention, the present invention provides a clipped thin-film resistor on a semiconductor device. The clipped thin-film resistor comprises a semiconductor substrate, a dielectric layer, and an out-gassing preventing layer, respectively. An isolated resistor layer is interposed between the underlying out-gassing preventing layer and an overlying protective layer, wherein the three layers together form a resistor island on the dielectric layer. The isolated resistor layer is clipped by the out-gassing preventing layer and the protective layer, and an insulating layer is formed on the semiconductor wafer covering the resistor island. Two tungsten plugs are positioned atop two respective ends of the resistor layer to electrically connect a metal wire to the isolated resistor layer.

It is an advantage of the present invention that the thin-film resistor of the present invention has a stable resistance and can be used in processes requiring smaller line-widths to reduce the overall area of the semiconductor product.

These and other objectives of the present invention will no doubt become obvious to those of ordinary skill in the art after having read the following detailed description of the preferred embodiment, which is illustrated in the various figures and drawings.

### BRIEF DESCRIPTION OF THE DRAWINGS

FIG. 1 is a schematic diagram of a thin-film resistor according to the prior art.

FIG. 2a to FIG. 2b are cross-sectional diagrams of a thin-film resistor according to the present invention.

FIG. 3a to FIG. 3d are schematic diagrams illustrating the method of forming a thin-film resistor according to the present invention.

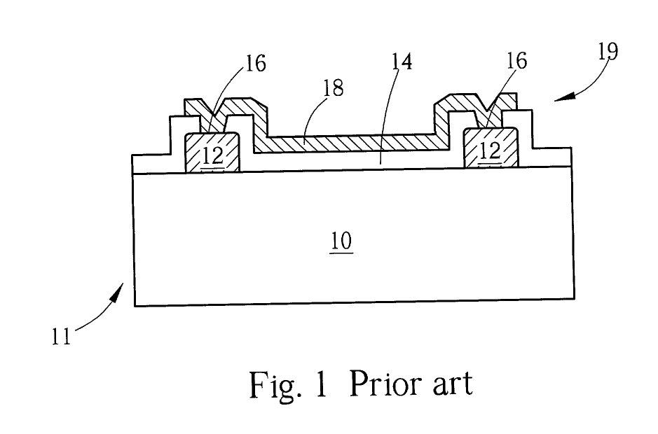

### DETAILED DESCRIPTION OF THE INVENTION

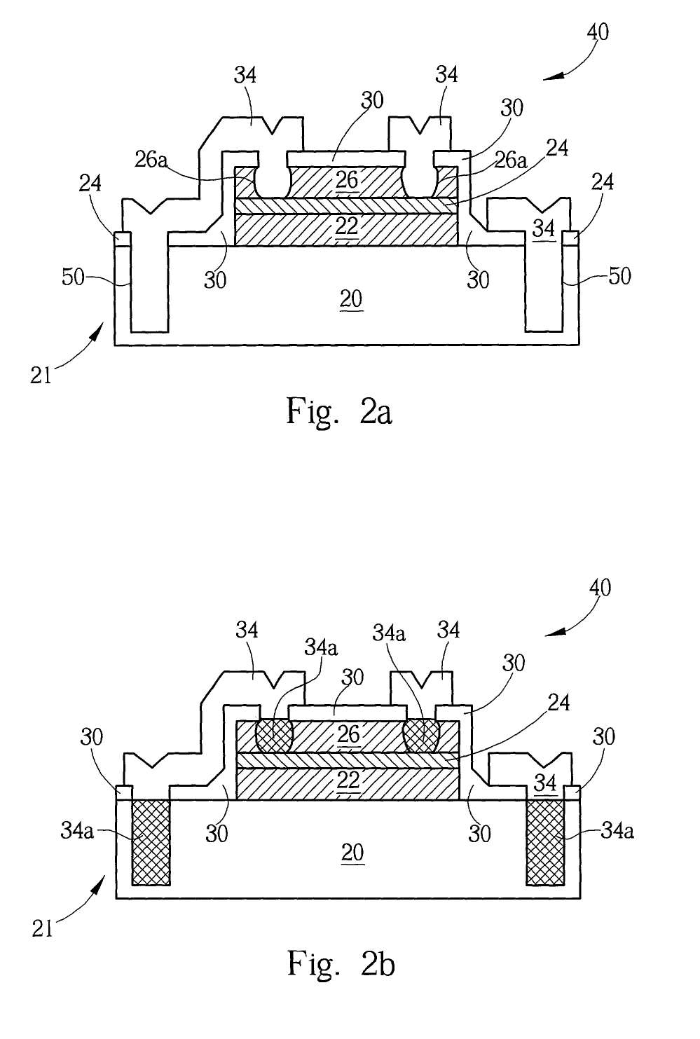

Structure of the Thin-Film Resistor Please refer to FIG. 2a. FIG. 2a is a cross-sectional diagram of a thin-film resistor 40 according to the present invention. As shown in FIG. 2a, the thin-film resistor 40 is formed on an inter-layer dielectric (ILD) layer 20, preferably a BPSG layer. A resistor layer 24 is interposed between an underlying isolating layer 22, preferably a silicon nitride layer, and a overlying protective layer 26, preferably a silicon nitride layer, to form a sandwiched resistor structure or a resistor island. The resistor layer 24 may be comprised of metal or metallic compounds, such as silicon chromium, nickel chromium, or the like. A well-defined via 26a is formed atop each respective end of the resistor layer 24 using photolithography and a two-step dry-wet etching processes. The result exposes portions of the resistor layer 24 and decreases the surface area of the stacked sandwiched resistor structure. A pattern of metal wires 34 comprised of an Al-based alloy is formed on the resistor structure to electrically connect with the resistor layer 24 through the vias 26a. An isolating layer 30 covers the sidewalls of the resistor island to prevent direct contact between the resistor layer 24 and the metal wire 34.

The protective layer 26 is positioned atop the resistor layer 24 in the defined area, and comprises a self-aligned H₃PO₄ wet etched via 26a atop each respective end of the resistor layer 24. The vias 26a are formed using a dry-etched insulating layer 30 as a wet-etching mask. The insulating layer 30 comprises two dry-etched openings 32 above the two wet-etched vias 26a in the protectivelayer26. The single photomask simultaneously defines the vias 26a and the contact holes 50. The insulating layer 30 is formed on the semiconductor wafer by a conventional chemical vapor deposition (CVD) process and covers the exposed surfaces of the protective layer 26, the resistor layer 24, and the dielectric layer 20. In another embodiment, the protective layer 26 may be composed of silicon oxy-nitride and the isolating layer 22 may be composed of silicon dioxide.

In FIG. 2b, another embodiment of the present invention, tungsten plugs 34a are formed to fill both the vias 26a and the contact holes 50 by means of conventional metal deposition and etch back processes. The tungsten plugs 34a electrically connect the two respective ends of the resistor layer. Two patterned conductive layers 34, also used as electrical wires to electrically connect the two respective ends of the resistor layer 24, are formed on the insulating layer 30 and the plugs 34a. The conductive layers 34 may be formed of aluminum, copper, or an aluminum-copper alloy.

### Process of the Preferred Embodiment

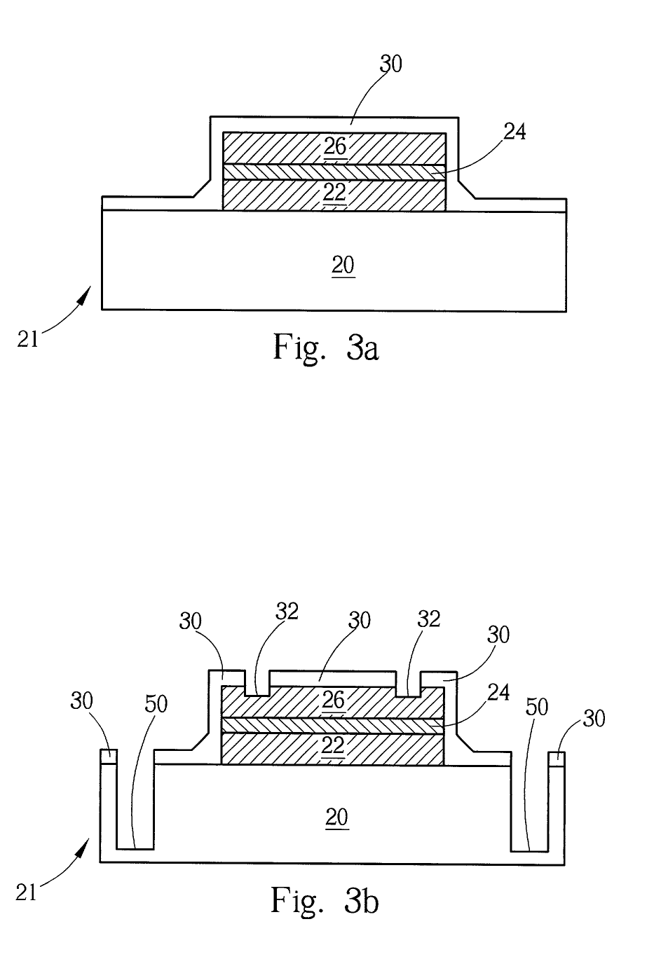

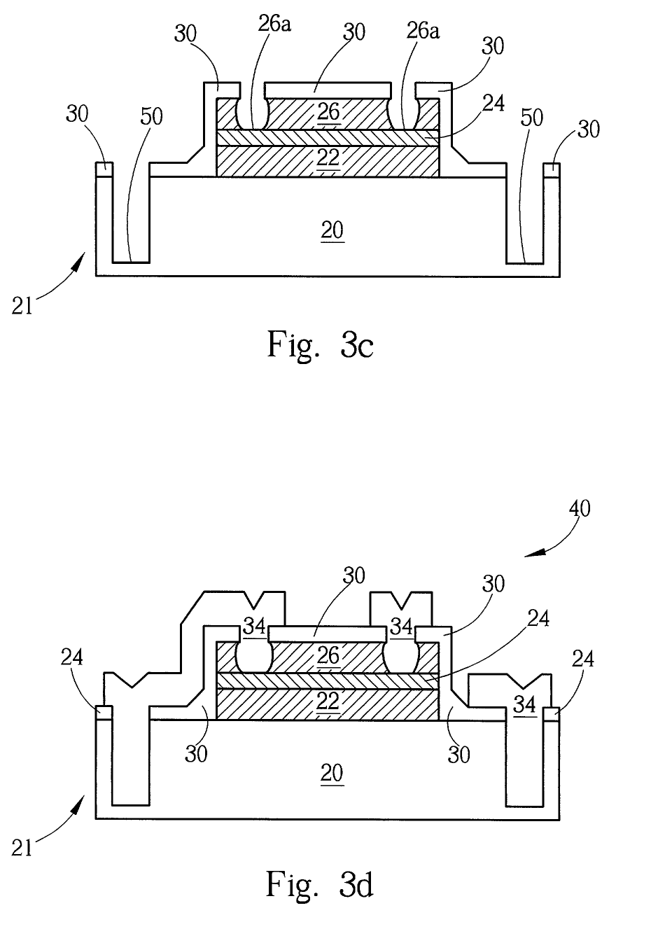

Please refer to FIG. 3a to FIG. 3d. FIG. 3a to FIG. 3d are cross-sectional diagrams illustrating the method of forming a thin-film resistor 40 according to the present invention. As noted, the thin-film resistor 40 of the present invention is formed on a dielectric layer 20 of a semiconductor wafer 21. The dielectric layer 20 may be formed of borophosphosilicate glass (BPSG), phosphosilicate glass (PSG), SiO₂, or so forth. Firstly, as shown in FIG. 3a, an isolating layer 22 of silicon nitride and a resistor layer 24 of silicon chromium are deposited, respectively, on the surface of the dielectric layer 20. Next, a protective layer 26 of silicon nitride is formed on the resistor layer 24. A lithographic and an anisotropic plasma dry-etching process are performed to define a resistor island consisting of a sandwiched stacked structure on the dielectric layer 20, exposing portions of the resistor layer 24 and the isolating layer 22. Then, an insulating layer 30 of silicon oxide is formed over the semiconductor wafer 21 by a CVD process to cover the exposed surfaces of the protective layer 26 and the resistor layer 24 of the resistor island, as well as the surface of the dielectric layer 20 outside the resistor island.

As shown in FIG. 3b, a second lithographic process and a second dry-etching process are performed on the insulating layer 30 to form two dry-etched openings 32 extending down to the surface of the protective layer 26. Both the openings 32 and the contact holes 50 are synchronously formed in the insulating layer 30 and the dielectric layer 20, respectively, by the same photomask defining the openings 32. The contact holes 50 form a path to electrically connect with other electrical components on the semiconductor wafer 21.

As shown in FIG. 3c, a wet-etching process is subsequently performed on the openings 32 of the insulating layer 30 to form two isotropically wet-etched vias 26a extending down to the surface of the resistor layer 24. The wet-etching process uses phosphoric acid (H₃PO₄) which does not affect the insulating layer 30, the dielectric layer 20 and, most importantly, the resistor layer 24.

As shown in FIG. 3d, a conducting layer 34 made of an Al-based alloy is then deposited on the surface of the semiconductor wafer 21 and filling the vias 26a. Next, a lithographic process and a metallic etching process are performed to remove the region of the conducting layer 34 outside a predetermined area to form a wire pattern to electrically connect with the two respective ends of the resistor layer 24.

In the thin-film resistor 40 of the present invention, the isolating layer 22, underneath the resistor layer 24, isolates out-gassing generated from the BPSG of the dielectric layer 20 to prevent the out-gassing from affecting the resistance value of the resistor layer 24. Meanwhile, the protective layer 26 protects the underlying resistor layer 24 from plasma damage caused by the dry-etching processes. A wet-etching process forms the two vias 26a of the protecting layer 26 and does not affect the resistor layer 24. Consequently, the resulting resistance of the resistor layer 24 of the thin-film resistor 40 of the present invention displays superior stability across wide temperature variations.

In the thin-film resistor 40 of the present invention, the side surfaces of the resistor layer 24 are covered by the insulating layer 30 so that the metal layer 34 connects with other components of the semiconductor wafer 21 without contacting the side of the resistor layer 24. As a result, there are fewer restrictions on the properties of the metal conducting layer 34. Except for the wet-etching process of the two vias 26a of the protective layer 26, all other etching processes are anisotropic dry-etching processes. Therefore, the area of the resistor layer 24 can be very small, with only the plugs 34a and the overlying conducting layers 34 serving as electrical connecting wires of the resistor layer 24. Thus, the present invention is suitable for processes with line-widths below 0.5 μm.

In comparison with the thin-film resistor 18 of the prior art, the thin-film resistor 40 of the present invention and the method of its formation involves sandwiching the resistor layer 24 between the overlying protective layer 26 and the underlying isolating layer 22. The insulating layer 30 is then deposited onto the surface of the semiconductor wafer 21 to stabilize the resistance of the resistor layer 24. With the exception of the wet-etching of the vias 26a in the protective layer 26, all other etching processes are anisotropic dry-etching processes. Therefore, the resistor layer 24 can be formed of a very small area. Thus, the method of the present invention not only produces a stable resistance in the thin-film resistor 40, but also allows line-widths below 0.5 μm to be used in processes.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor device having a thin-film resistor positioned on a dielectric layer of a semiconductor wafer comprising:
a resistor island comprised of a resistor layer formed on the dielectric layer and a protective layer laminated on the resistor layer, the protective layer having two self-aligned wet etched vias formed within the protective layer atop two respective ends of the resistor layer;
an insulating layer formed on the semiconductor wafer and covering the resistor island; and
two metal wires, positioned atop two respective ends of the resistor layer, to electrically connect with the isolated resistor layer.

2. The semiconductor device having a thin-film resistor of claim 1 wherein the resistor layer is composed of CrSi.

3. The semiconductor device having a thin-film resistor of claim 1 wherein the protective layer is composed of silicon nitride.

4. The semiconductor device having a thin-film resistor of claim 1 wherein the via is wet etched by means of a phosphoric acid solution.

5. The semiconductor device having a thin-film resistor of claim 1 further comprising an isolating layer positioned between the resistor layer and the dielectric layer, the isolating layer isolating out-gassing produced by the borophosphosilicate glass of the dielectric layer to prevent the out-gassing from affecting the resistance of the resistor layer.

6. The semiconductor device having a thin-film resistor of claim 5 wherein the insulating layer is composed of silicon oxide, the dielectric layer composed of borophosphosilicate glass (BPSG), and the isolating layer composed of silicon nitride.

7. The semiconductor device having a thin-film resistor of claim 1 wherein the plug is composed of tungsten.

8. The semiconductor device having a thin-film resistor of claim 1 wherein the metal wire is composed of Al-based alloy.

9. A semiconductor device having a clipped thin-film resistor comprising:
a semiconductor substrate;
a dielectric layer formed on the semiconductor substrate;
an out-gassing preventing layer formed on the dielectric layer;
an isolated resistor layer interposed between the underlying out-gassing preventing layer and an overlying protective layer, wherein the three layers together form a resistor island on the dielectric layer, and the isolated resistor layer is clipped by the out-gassing preventing layer and the protective layer;
an insulating layer formed on the semiconductor wafer and covering the resistor island; and
two tungsten plugs, positioned atop two respective ends of the resistor layer, to electrically connect a metal wire with the isolated resistor layer;
wherein each tungsten plug first fills a self-aligned wet etched via, formed within the protective layer atop two respective ends of the resistor layer, and then etched back, wherein the protective layer protects the resistor layer from damage during the formation of the via.

10. The semiconductor device having a thin-film resistor of claim 9 wherein the resistor layer is composed of CrSi.

11. The semiconductor device having a thin-film resistor of claim 9 wherein the protective layer is composed of silicon nitride.

12. The semiconductor device having a thin-film resistor of claim 9 wherein the via is wet etched by means of a phosphoric acid solution.

13. The semiconductor device having a thin-film resistor of claim 9 further comprising an isolating layer positioned between the resistor layer and the dielectric layer, the isolating layer isolating out-gassing produced by the borophosphosilicate glass of the dielectric layer to prevent the out-gassing from affecting the resistance of the resistor layer.

14. The semiconductor device having a thin-film resistor of claim 13 wherein the insulating layer is composed of silicon oxide, the dielectric layer composed of borophosphosilicate glass (BPSG), and the isolating layer composed of silicon nitride.

15. The semiconductor device having a thin-film resistor of claim 9 wherein the plug is composed of tungsten.

16. The semiconductor device having a thin-film resistor of claim 9 wherein the metal wire is composed of Al-based alloy.
